(19) United States
(12) Patent Application Publication
(10) Pub. No.: US 2013/0256023 A1
(43) Pub. Date: Oct. 3, 2013

(54) PRINTED CIRCUIT BOARD AND METHOD OF MANUFACTURING THE SAME

(71) Applicant: SAMSUNG ELECTRO-MECHANICS CO., LTD., (US)

(72) Inventor: Eung Soo Kim, Suwon (KR)

(73) Assignee: SAMSUNG ELECTRO-MECHANICS CO., LTD., Suwon (KR)

(21) Appl. No.: 13/853,534

(22) Filed: Mar. 29, 2013

(30) Foreign Application Priority Data
Mar. 30, 2012 (KR) 10-2012-0033353

(51) Int. Cl. H05K 3/10; H05K 1/11; H05K 1/02

(52) U.S. Cl. CPC H05K 3/10; H05K 1/02; H05K 1/111
USPC 174/261; 174/250; 427/97.1; 427/97.3; 156/256

(57) ABSTRACT

Disclosed herein is a printed circuit board, including: a base substrate having an outer layer circuit; an insulating layer formed partially on the base substrate; and a circuit layer formed on the insulating layer.

CROSS REFERENCE TO RELATED APPLICATION

This application claims the benefit of Korean Patent Application No. 10-2012-0033353, filed on Mar. 30, 2012, entitled “Printed Circuit Board and Method of Manufacturing for the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, the rapid development in semiconductor technology necessary for signal processing has lead to remarkable growth of semiconductor devices. Also, semiconductor packages such as a system in package (SIP), a chip sized package (CSP), a flip chip package (FCP), and the like, according to which electronic devices such as semiconductor devices and the like are mounted on a printed circuit board in advance, are being actively developed.

The recent trends are that the size of dies is reduced due to the development of semiconductor technology, which also leads to the reduction in size of a package substrate for mounting semiconductor devices and the like thereon, and thus, the area in which bonding pads formed on the substrate for electric connection with electronic devices are provided is decreased. Meanwhile, as the I/O counts of a semiconductor device increase, the number of patterns to be formed on the package substrate, and thus, the patterns in a chip mount region need to be finely formed. However, this process has many restrictions.

In addition, as the size of products becomes smaller, the thickness of the package substrate inserted into the products needs to be further decreased.

Meanwhile, a printed circuit board for a package and a method thereof according to the prior art are disclosed in U.S. Pat. No. 7,217,999.

### SUMMARY OF THE INVENTION

The present invention has been made in an effort to provide a printed circuit board and a method of manufacturing the same, capable of increasing wiring density in a chip mounting region.

Further, the present invention has been made in an effort to provide a printed circuit board and a method of manufacturing the same, capable of lowering the entire height of a package.

Further, the present invention has been made in an effort to provide a printed circuit board and a method of manufacturing the same, capable of saving manufacturing costs by reducing the use of an insulation material.

According to a preferred embodiment of the present invention, there is provided a printed circuit board, including: a base substrate having an outer layer circuit; an insulating layer formed partially on the base substrate; and a circuit layer formed on the insulating layer.

The insulating layer may be formed on the base substrate to expose a portion of a surface of the base substrate and a portion of the external circuit.

Here, a lateral surface in a thickness direction of the insulating layer may slope downward from an upper surface of the insulating layer in an outer direction thereof.

The circuit layer may include: connection pads formed on the insulating layer; and circuit patterns connected with the connection pads and extended to an exposed surface of the 6e substrate passing through a lateral surface of the insulating layer.

The circuit layer may further include vias electrically connecting the connection pads with connection pads formed on the base substrate while passing through the insulating layer.

The insulating layer may be formed in a semiconductor chip mounting region.

According to another preferred embodiment of the present invention, there is provided a method of manufacturing a printed circuit board, the method including: preparing a base substrate having an outer layer circuit; forming an insulating layer partially on the base substrate; and forming a circuit layer on the insulating layer.

The forming of the insulating layer partially on the base substrate may be performed to expose a portion of a surface of the base substrate and a portion of the outer layer circuit.

The forming of the insulating layer partially on the base subs ate may include: disposing a patterned mask above the base substrate; allowing a liquid phase insulation material to flow into a patterned portion of the mask through a screen printing process; removing the mask; and curing the liquid insulation material.

The forming of the insulating layer partially on the base substrate may include: disposing a film insulation material on the base substrate; attaching the insulating layer to the base substrate by pressing and cutting a portion of the film insulation material, which corresponds to a region where the insulating layer is to be formed, on the base substrate; and pressing an entire surface of the base substrate by using a roller.

The forming of the circuit layer on the insulating layer may include: forming a patterned plating resist on the insulating layer; forming a plating layer in a patterned portion of the patterned plating resist by performing a plating process; and removing the patterned plating resist.

The forming of the patterned plating resist may include: forming a plating resist on the insulating layer; forming a step height compensating film on the plating resist; disposing a patterned mask above the step height compensating film; curing a portion of the plating resist, which corresponds to a patterned portion of the mask, by performing an exposing process; removing the step height compensating film; and removing an un-cured portion of the plating resist by performing a developing process.

The step height compensating film may be formed of at least one selected from polyethylene terephthalate (PET), Teflon, and biaxially oriented polypropylene.

The method may further include: before the forming of the patterned plating resist on the insulating layer, forming a seed layer on the insulating layer; and, after the removing of the plating resist, removing an exposed portion of the seed layer.

The method may further include, before the forming of the seed layer on the insulating layer, forming via holes in the insulating layer.

The plating resist may be a dry film (DF).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plane view showing a structure of a printed circuit board according to a preferred embodiment of the present invention;

FIG. 2 is a cross sectional view of the printed circuit board according to the preferred embodiment of the present invention as taken along the line A-A′ of FIG. 1; and

FIGS. 3 to 12 are cross-sectional views sequentially showing a method for manufacturing the printed circuit board according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

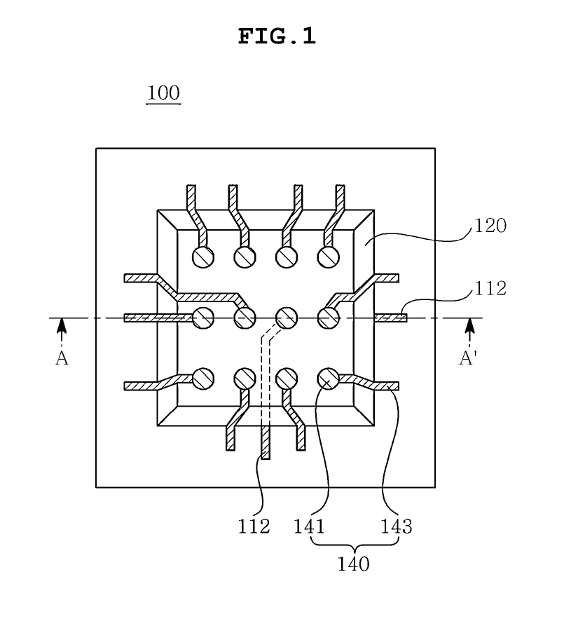

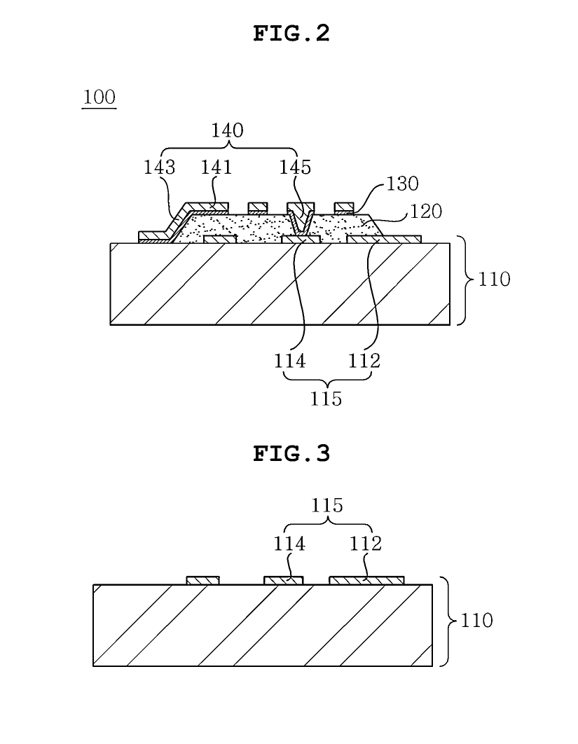

FIG. 1 is a plane view showing a structure of a printed circuit board according to a preferred embodiment of the present invention; and FIG. 2 is a cross sectional view of the printed circuit board according to the preferred embodiment of the present invention as taken along the line A-A′ of FIG. 1.

Referring to FIGS. 1 and 2, a printed circuit board 100 according to a preferred embodiment of the present invention may include a base substrate 110 having an outer layer circuit 115; an insulating layer 120 partially formed on the base substrate 110; and a circuit layer 140 formed on the insulating layer 120.

In the present preferred embodiment, the base substrate 110 is a circuit board in which at least one layer of circuit is formed on an insulation material, and preferably may be a printed circuit board. For convenience of explanation, specific constitutions of an inner layer circuit have been omitted in the present drawings. However, those skilled in the art will recognize that a conventional circuit board in which at least one of circuit is formed on an insulation material may be employed as the base substrate 110.

As the insulation material, a conventional resin insulation material may be used. As the resin insulation material, a thermosetting resin like an epoxy resin, such as, FR-4, bismaleimide triazine (BT), ajinomoto build up film (ABF), or the like, which is known as a material of conventional resin substrates; a thermoplastic resin such as polyimide; or a resin in which a reinforcement material such as a glass fiber or an inorganic filler is impregnated with the thermosetting resin or the thermoplastic resin, for example, a prepreg, may be used, and also, the thermosetting resin and/or a photo-setting resin, or the like, may be used. However, the resin insulation material is not particularly limited thereto.

The outer circuit layer 115 may include connection pads 114, circuit patterns 112, and vias (not shown), and any material that can be used as a conductive metal for a circuit in a circuit substrate field may be employed without limitation. It is normal to employ copper in a printed circuit board.

In the present preferred embodiment, the insulating layer 120 may be partially formed on the base substrate 110 to expose a portion of a surface of the base substrate 110 and a portion of the outer layer circuit 115, but is not particularly limited thereto.

In addition, a lateral surface in a thickness direction of the insulating layer 120, as shown in FIG. 2, may slope downward from an upper surface of the insulating layer 120 in an outer direction thereof, but is not particularly limited thereto.

In addition, in the present invention, a region where the insulating layer 120 may be a chip mounting region, but is not particularly limited thereto. Any region that can require high wiring density may be applied therefore.

That is, in the prior art, any multilayer printed circuit board has taken the form in which an insulating layer is formed on the entire surface of a substrate regardless of whether the wiring density is high or low, but in the present invention, the insulating layer is partially formed in only the region requiring high wiring density.

As such, the use of an insulating material is reduced by forming the insulating layer 120 partially on the substrate but not entirely on the substrate, so that the manufacturing costs can be reduced.

Also, the insulating layer 120 is not formed on the entire surface of the substrate, to thereby prevent the increase in thickness of the substrate, and thus, a thin film type substrate can be easily manufactured.

In the present preferred embodiment, the circuit layer may include connection pads 141 formed on the insulating layer 120; and circuit patterns 143 connected with the connection pads 141 and extended to an exposed surface of the base substrate 110 passing through a lateral surface of the insulating layer 120.

Therefore, the circuit patterns 143 in the present preferred embodiment may be formed in a crooked type as shown in FIGS. 1 and 2.

In addition, the circuit layer 140 may include vias 145. Each of the vias 145 electrically connects the connection pad 141 to the connection pad 114 formed on the base substrate 110 while passing through the insulating layer 120.

In the present invention, for example, the circuit layer 140 basically is extended from a surface of the insulating layer 120 to a surface of the base substrate 110. Here, in the case where pattern formation is difficult form on the surface of the insulating layer 120 (for example, in the case where the minimum space for pattern formation is not secured), the circuit layer 140 may be extended to the surface of the base substrate 110 passing through the insulating layer 120.

Although not shown in the drawings, a solder resist layer (not shown) may be further formed on the insulating layer 120 and the base substrate 110.

Here, the solder resist layer (not shown) may serve as a protection layer protecting an outermost layer circuit, and may be formed for electric insulation. The solder resist layer (not shown) may have opening portions for exposing the connection pads 141 on the insulating layer 120.

The solder resist layer may be constituted of, for example, a solder resist ink, a solder resist film, or an encapsulant, according to the technology known in the art, but is not particularly limited thereto.

In addition, a surface treatment layer may be further formed on the connection pads 141 exposed by the opening portions, and a semiconductor chip (not shown) may be mounted on the exposed connection pads 141.

Method of Manufacturing Printed Circuit Board

FIGS. 3 to 12 are cross-sectional views sequentially showing a method of manufacturing a printed circuit board according to a preferred embodiment of the present invention.

First, referring to FIG. 3, a base substrate 110 having an outer layer circuit 115 is prepared.

In the present preferred embodiment, the base substrate 110 is a circuit board in which at least one layer of circuit is formed on an insulation material, and preferably may be a printed circuit board.

For convenient explanation, specific constitutions of an inner layer circuit is not omitted in the present drawings. However, those skilled in the art will recognize that a conventional circuit board in which at least one layer of circuit is formed on an insulation material may be employed as the base substrate 110.

As the insulation material, a conventional resin insulation material may be used. As the resin insulation material, a thermosetting resin like an epoxy resin, such as, FR-4, bismaleimide triazine (BT), ajinomoto build up film (ABF), or the like, which is known as a material of conventional resin substrates; a thermoplastic resin such as polyimide; or a resin in which a reinforcement material such as a glass fiber or an inorganic filler is impregnated with the thermosetting resin or the thermoplastic resin, for example, a prepreg, may be used, and also, the thermosetting resin and/or a photo-setting resin, or the like, may be used. However, the resin insulation material is not particularly limited thereto.

The outer circuit layer 115 may include connection pads 114, circuit patterns 112, and vias (not shown), and any material that can be used as a conductive metal for a circuit in a circuit substrate field may be employed without limitation. It is general to employ copper in a printed circuit board.

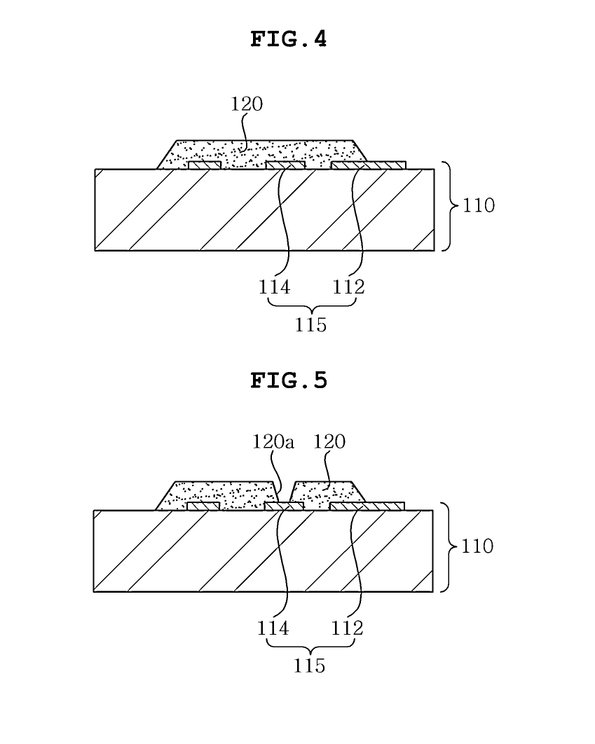

Next, referring to FIG. 4, an insulating layer 120 is formed partially on the base substrate 110.

Here, a conventional resin insulation material like the above-described insulation material may be used for the insulating layer 120.

Here, the insulating layer 120 may be formed such that a portion of a surface of the base substrate 110 and a portion of the outer layer circuit 115 are exposed, but is not particularly limited thereto.

In the present preferred embodiment, the forming of the insulating layer 120 partially on the base substrate 110 may be performed by one of the following methods. However, this is merely an example for illustration, but is not limited thereto.

As the first example, there may be employed a method of disposing a patterned mask above the base substrate 110, performing a screen printing process so as to allow a liquid phase insulation material to flow into a patterned portion of the mask, and removing the mask, followed by curing.

As the second example, there may be employed a method of disposing a film insulation material on the base substrate 110, attaching the film insulation material onto a portion of the base substrate 110, on which the insulating layer 120 is to be formed, by pressing with a roller, and then cutting the film insulation material using a cutting unit.

The method as above is repeated to attach the film insulation material to the entire region requiring formation of the insulating layer 120, and then the entire surface of the substrate is again pressed by using a roller, so that the forming of the insulating layer 120 may be completed.

By forming the insulating layer 120 as the above manner, a lateral surface in a thickness direction of the insulating layer 120 may slope downward from an upper surface of the insulating layer 120 in an outer direction thereof, but is not particularly limited thereto.

As in the present preferred embodiment, the use of the insulating material can be reduced by forming the insulating layer 120 partially on the base substrate 110 but not entirely on the base substrate 110.

Then, referring to FIG. 5, via holes 120a are formed in the insulating layer 120.

In the present preferred embodiment, the forming of the via holes 120a may be performed or not be performed according to the need.

For example, in the case where the minimum region for forming circuit patterns is difficult to secure on a surface of the insulating layer 120, the vias 145 are formed such that they are extended to the surface of the base substrate 110. In this case, the above step may be performed, but, if this is not the case, the above step may not be performed and may move on the next step.

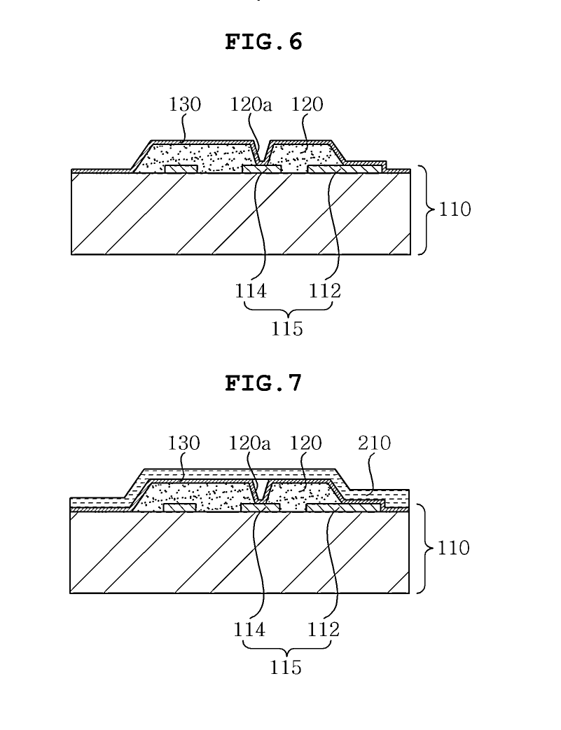

Then, referring to FIG. 6, a seed layer 130 is formed on the insulating layer 120.

The seed layer 130 is formed in order to perform an electroplating process in the subsequent process. The seed layer 130 may be formed of copper, but is not particularly limited thereto.

Then, referring to FIG. 7, a plating resist 210 is formed on the seed layer 130.

In the present preferred embodiment, the plating resist 210 may be a dry film (DF), but is not particularly limited thereto.

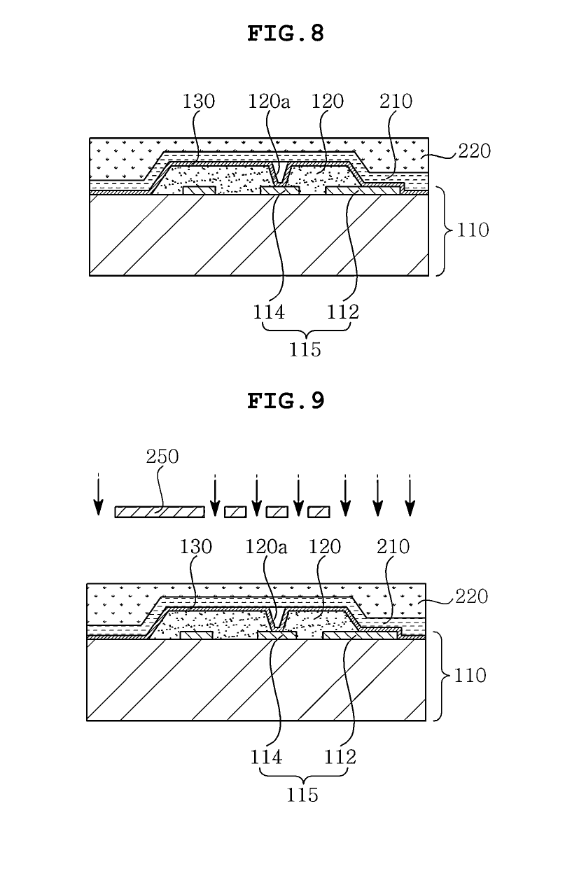

Then, referring to FIG. 8, a step height compensating film 220 is formed on the plating resist 210.

In the present preferred embodiment, the step height compensating film 220 is formed to compensate the step height generated on the plating resist 210.

That is, in the present preferred embodiment, since the insulating layer 120 is partially formed, the step height is generated between the base substrate 110 and the insulating layer 120. As such, when the plating resist 210 is formed on the base substrate 110 and the insulating layer 120, the step height is generated between the plating resist 210 formed on the base substrate 110 and the plating resist 210 formed on the insulating layer 120, resulting in an uneven surface. In this condition, the patterning of the plating resist 210 may not be easy.

Therefore, in the present preferred embodiment, the step height compensating film 220 is formed on the plating resist 210 in order to compensate the step height generated on the plating resist 210. That is, the step height compensating film 220 is formed on the plating resist 210 in order to make an even surface.

Here, the step height compensating film 220 may be formed of at least selected from polyethylene terephthalate (PET), Teflon, and biaxially oriented polypropylene, but is not particularly limited thereto. Any polymer film that has releasing property may be used.

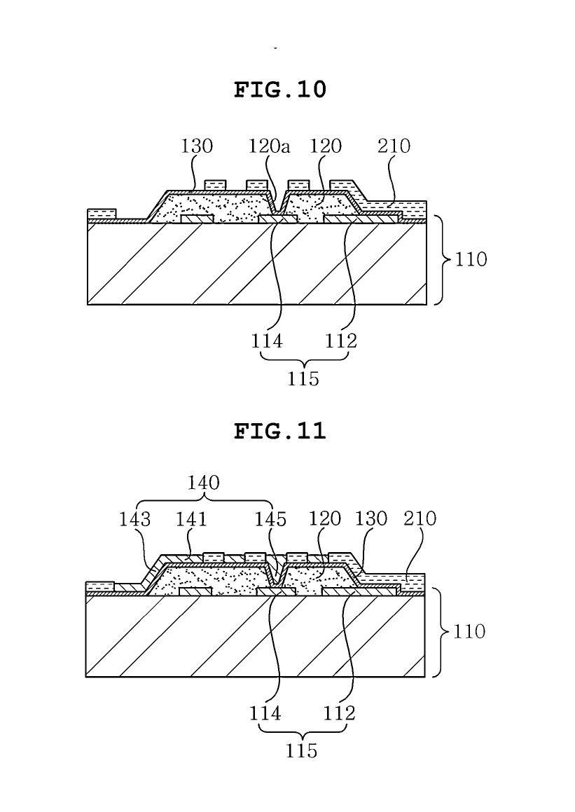

Then, referring to FIGS. 9 and 10, a patterned mask 250 is disposed above the step height compensating film 220, and then a photolithographic method including exposing and developing processes is performed to pattern the plating resist 210. This will be described in detail as follows.

First, the mask 250 is disposed above the step height compensating film 220, and then the exposing process is performed to cure a portion of the plating resist 210, which corresponds to a patterned portion of the mask 250. Here, the step height compensating film 220 enables UV (ultraviolet light) used in the exposing process to pass therethrough as it is.

Then, the step height compensating film 220 is removed, and then the developing process using a developing liquid to remove un-cured portion of the plating resist 210, to thereby pattern the plating resist 210 as shown in FIG. 10.

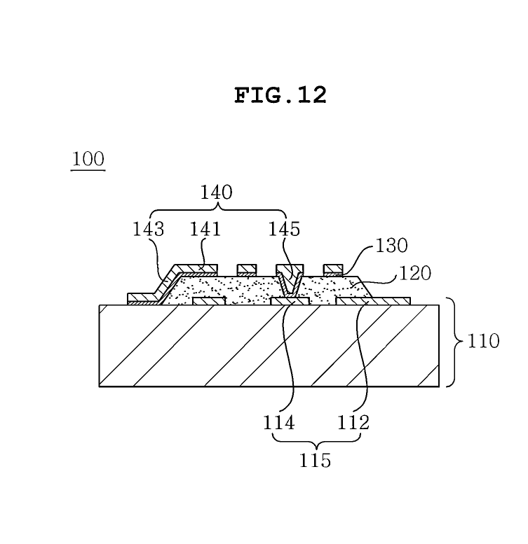

Then, as shown in FIGS. 11 and 12, the plating process is performed to form a plating layer, and the plating resist 210 is removed to form a circuit layer 140.

As the subsequent process, a solder resist layer (not shown) may be further formed on the base substrate 110 and the insulating layer 120. Here, the solder resist layer (not shown) may include opening portions exposing the connection pads 141 in the circuit layer 140.

In addition, a surface treatment layer may be further formed on the exposed connection pads 141 as necessary, and a semiconductor chip (not shown) may be mounted on the exposed connection pads 141.

As set forth above, according to the present invention, the insulating material is formed partially on the base substrate but not entirely on the base substrate, to thereby reduce the use thereof, and thus, the manufacturing costs can be reduced.

Further, according to the present invention, the insulating layer is additively formed in a region requiring high wiring density, which can facilitate the designing of wiring designing to have fine pitches at high density.

Further, according to the present invention, the additional forming of the insulating layer is partially performed, to thereby prevent the increase in thickness of the substrate, and thus, the thin film type substrate can be easily manufactured.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate having an outer layer circuit;
an insulating layer formed partially on the base substrate; and
a circuit layer formed on the insulating layer.

2. The printed circuit board as set forth in claim 1, wherein the insulating layer is formed on the base substrate to expose a portion of a surface of the base substrate and a portion of the outer layer circuit.

3. The printed circuit board as set forth in claim 1, wherein a lateral surface in a thickness direction of the insulating layer slopes downward from an upper surface of the insulating layer in an outer direction thereof.

4. The printed circuit board as set forth in claim 1, wherein the circuit layer includes:
connection pads formed on the insulating layer; and
circuit patterns connected with the connection pads and extended to an exposed surface of the base substrate passing through a lateral surface of the insulating layer.

5. The printed circuit board as set forth in claim 4, wherein the circuit layer further include vias electrically connecting the connection pads with connection pads formed on the base substrate while passing through the insulating layer.

6. The printed circuit board as set forth in claim 1, wherein the insulating layer is formed in a semiconductor chip mounting region.

7. A method of manufacturing a printed circuit board, the method comprising:
preparing a base substrate having an outer layer circuit;
forming an insulating layer partially on the base substrate; and
forming a circuit layer on the insulating layer.

8. The method as set forth in claim 7, wherein the forming of the insulating layer partially on the base substrate is performed to expose a portion of a surface of the base substrate and a portion of the outer layer circuit.

9. The method as set forth in claim 7, wherein the forming of the insulating layer partially on the base substrate includes:
disposing a patterned mask above the base substrate;
allowing a liquid phase insulation material to flow into a patterned portion of the mask through a screen printing process;
removing the mask; and
curing the liquid insulation material.

10. The method as set forth in claim 7, wherein the forming of the insulating layer partially on the base substrate includes:
disposing a film insulation material on the base substrate;
attaching the insulating layer to the base substrate by pressing and cutting a portion of the film insulation material, which corresponds to a region where the insulating layer is to be formed, on the base substrate; and
pressing an entire surface of the base substrate by using a roller.

11. The method as set forth in claim 7, wherein the forming of the circuit layer on the insulating layer includes:
forming a patterned plating resist on the insulating layer;
forming a plating layer in a patterned portion of the patterned plating resist by performing a plating process; and
removing the patterned plating resist.

12. The method as set forth in claim 11, wherein the forming of the patterned plating resist includes:
forming a plating resist on the insulating layer;
forming a step height compensating film on the plating resist;
disposing a patterned mask above the step height compensating film;
curing a portion of the plating resist, which corresponds to a patterned portion of the mask, by performing an exposing process;
removing the step height compensating film; and
removing an un-cured portion of the plating resist by performing a developing process.

13. The method as set forth in claim 12, wherein the step height compensating film is formed of at least one selected from polyethylene terephthalate (PET), Teflon, and biaxially oriented polypropylene.

14. The method as set forth in claim 11, further comprising:
before the forming of the patterned plating resist on the insulating layer, forming a seed layer on the insulating layer; and
after the removing of the plating resist, removing an exposed portion of the seed layer.

15. The method as set forth in claim 14, further comprising, before the forming of the seed layer on the insulating layer, forming via holes in the insulating layer.

16. The method as set forth in claim 11, wherein the plating resist is a dry film (DF).
